(19) United States
(12) Patent Application Publication
(10) Pub. No.: US 2021/0063884 A1
(43) Pub. Date: Mar. 4, 2021

(54) MASK-LESS LASER DIRECT IMAGING SYSTEM

(71) Applicant: SHUZ TUNG MACHINERY INDUSTRIAL CO.,LTD., TAICHUNG CITY (TW)

(72) Inventors: KUO-SHU HUNG, TAICHUNG CITY (TW); CHUN-HSUEN LIU, TAICHUNG CITY (TW); MING-HUNG CHANG, TAICHUNG CITY (TW); SHU-CHENG LIAO, TAICHUNG CITY (TW)

(21) Appl. No.: 16/590,705

(22) Filed: Oct. 2, 2019

(30) Foreign Application Priority Data
Sep. 2, 2019 (TW) 108131555

(51) Int. Cl. G03F 7/20

(52) U.S. Cl. CPC G03F 7/2053; G02B 26/125; G03F 7/70275; G03F 7/2059

(57) ABSTRACT

A reflective mask-less laser direct imaging system includes laser equipment that includes laser light sources, focusing lenses, a scanner and a compensating lens. The focusing lenses focus light beams onto a photosensitive layer of a substrate from the laser light sources. The scanner includes a rotatable polygonal mirror formed with multiple facets used to reflect the light beams to the substrate from the focusing lenses. The compensating lens includes a convex surface pointed at the polygonal mirror and a flat surface pointed at the compensating lens. The light beams go from the polygonal mirror into the compensating lens via the convex surface. The light beams leave the compensating lens via the flat surface before heading for the substrate.

### BACKGROUND OF INVENTION

### 1. Field of Invention

The present invention relates to an imaging system and, more particularly, to a mask-less laser direct imaging system.

### 2. Related Prior Art

To make display panels, semiconductor products and printed circuit boards, exposure is an important process. Unlike masks are used in exposure processes conventionally, laser direct imaging (“LDI”) is non-mask photolithography. An LDI system uses a laser beam to scan a photosensitive layer of a substrate to provide a desired exposed pattern. For example, Taiwanese Patent Nos. 523968, 1666526, 1650615 and 1620038 and Taiwanese Patent Application Publication Nos. 201543178 and 200634442 disclose LDI systems. In these LDI systems, rotatable prisms are used. The rotatable prisms are penetrating prisms or reflective prisms.

The present invention is therefore intended to obviate or at least alleviate the problems encountered in prior art.

### SUMMARY OF INVENTION

It is the primary objective of the present invention to provide a reflective mask-less laser directing imaging system.

To achieve the foregoing objectives, the reflective mask-less laser direct imaging system includes a platform, a carrier, a gantry and a laser-based imaging device. The carrier is movable on the platform along a Y-axis and operable to carry a substrate coated with a photosensitive layer. The gantry is supported on the platform. The laser-based imaging device is connected to the gantry and operable to scan the photosensitive layer of the substrate while the carrier is moving the substrate under and past the gantry. The laser-based imaging device includes laser sources, focusing lenses, a reflective scanner and a compensating lens. The laser sources are arranged along an X-axis and operable to emit parallel laser beams. The focusing lenses focus the laser beams onto the photosensitive layer of the substrate from the laser sources. The reflective scanner includes two bearings, a polygonal mirror and a motor. The bearings are connected to the gentry. The polygonal mirror includes two terminal sections supported on the bearings and facets for reflecting the laser beams to the substrate from the focusing lenses. Each of the facets does not extend parallel or perpendicular to the optical axis of the corresponding focusing lens while reflecting the corresponding laser beam that go through the corresponding focusing lens. The motor is operatively connected to one of the terminal sections of the polygonal mirror. The compensating lens is located between the polygonal mirror and the substrate and includes a convex face pointed at the polygonal mirror and a planar face pointed at the substrate. The laser beams enter the compensating lens through the convex face and leave the compensating lens through the planar face before heading for the photosensitive layer of the substrate.

In an aspect, the compensating lens is a single cylindrical lens.

In an alternative aspect, the compensating lens includes spherical or aspherical lenses.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a perspective view of a reflective mask-less laser direct imaging system according to the preferred embodiment of the present invention;

FIG. 2 is a top view of a laser-based imaging device used in the reflective mask-less laser direct imaging system shown in FIG. 1;

FIG. 3 is a perspective view of the laser-based imaging device shown in FIG. 2; and

FIGS. 4 through 6 are side views of the laser-based imaging device shown in FIG. 2 in various positions.

### DETAILED DESCRIPTION OF PREFERRED EMBODIMENT

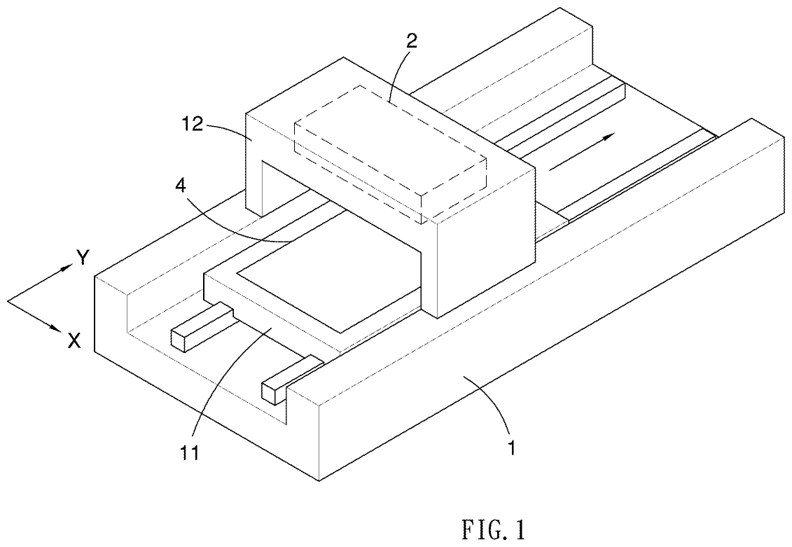

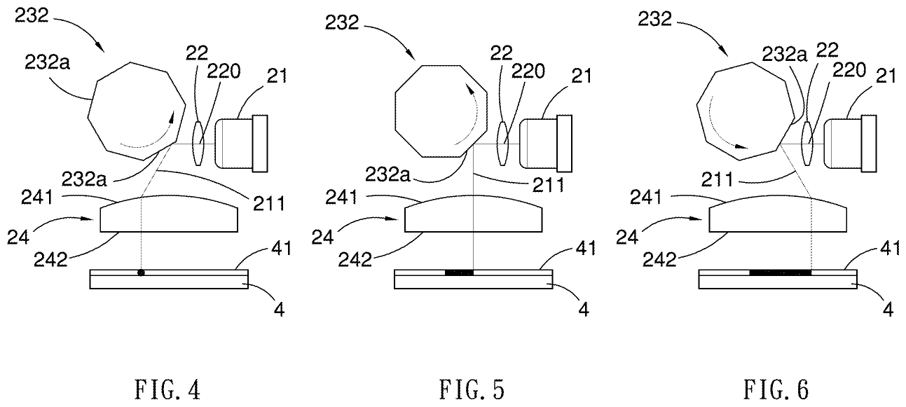

Referring to FIG. 1, a reflective mask-less laser direct imaging system includes a platform 1, a carrier 11, a gantry 12 and a laser-based imaging device 2 according to the preferred embodiment of the present invention. The carrier 11 is movable on the platform 1 along a coordinate axis Y. The gantry 12 is supported on the platform 1. The laser-based imaging device 2 is connected to the gantry 12. The carrier 11 is used to carry and move a substrate 4 on the platform 1. A photosensitive layer 41 of the substrate 4 is exposed to the laser-based imaging device 2 while the carrier 11 is moving under and past the gantry 12 (FIG. 4).

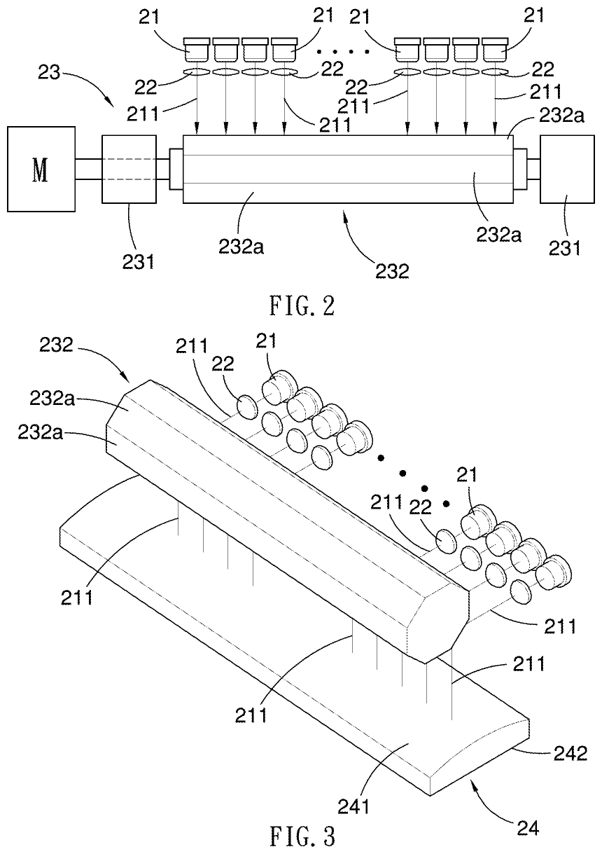

Referring to FIGS. 2 and 3, the laser-based imaging device 2 includes laser sources 21, focusing lenses 22, a reflective scanner 23 and a compensating lens 24. The laser sources 21 are arranged along a coordinate axis X (FIG. 1). The laser sources 21 are used to cast parallel laser beams 211. Each of the laser sources 21 is a laser diode or a light-emitting diode. The laser diode is an ultraviolet laser diode for example. The light-emitting diode is an ultraviolet light-emitting diode for example.

The focusing lenses 22 receive the laser sources 21 from the laser beams 211. Each of the focusing lenses 22 focuses a corresponding one of the laser beams 211 on the photosensitive layer 41 of the substrate 4 in a manner to be described.

The reflective scanner 23 includes a motor M, two bearings 231 and a rotatable polygonal mirror 232. The motor M is a servomotor or a stepper motor. The bearings 231 are preferably air bearings connected to the gentry 12. The polygonal mirror 232 is formed with two terminal sections supported on the bearings 231. The motor M is connected to one of the terminal sections of the polygonal mirror 232 so that motor M is operable to rotate the polygonal mirror 232. Preferably, the polygonal mirror 232 is an octagonal mirror that includes eight facets 232a. Referring to FIGS. 4 to 6, the facets 232a reflect the laser beams 211 that go through the focusing lenses 22, thereby casting the laser beams 211 onto the substrate 4. Each of the facets 232a of the polygonal mirror 232 does not extend parallel or perpendicular to the optical axis 220 of the corresponding focusing lens 22 while reflecting the corresponding laser beam 211 that go through the corresponding focusing lens 22.

The compensating lens 24 is located between the polygonal mirror 232 and the substrate 41. The compensating lens 24 includes a convex face 241 pointed at the polygonal mirror 232 and a planar face 242 pointed at the substrate 4. The laser beams 211 from the polygonal mirror 232 enter the compensating lens 24 via the convex face 241. Then, the laser beams 211 leave the compensating lens 24 via the planar face 242 and head for the photosensitive layer 41 of the substrate 4.

The compensating lens 24 is used to modify aberration caused by the focusing lenses 22 and reduce light spots cast by the laser beams 211, thereby increasing the resolution of an exposed pattern. In the preferred embodiment, the compensating lens 24 is a cylindrical lens extending parallel to the polygonal mirror 232. However, in another embodiment, the compensating lens 24 is actually a row of spherical or aspherical lenses. Such aspherical lenses can be made of glass for example

Referring to FIGS. 4 through 6, a laser beam 211 is reflected from a facet 232a of the polygonal minor 232. The laser beam 211 reaches various locations on the substrate 4 because the polygonal minor 232 is in rotation.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A reflective mask-less laser direct imaging system comprising a platform (1), a carrier (11) movable on the platform (1) along a Y-axis and operable to carry a substrate (4) coated with a photosensitive layer (41), a gantry (12) supported on the platform (1), and a laser-based imaging device (2) connected to the gantry (12) and operable to scan the photosensitive layer (41) of the substrate (4) while the carrier (11) is moving the substrate (4) under and past the gantry (12), wherein the laser-based imaging device (2) comprises:
laser sources (21) arranged along an X-axis and operable to emit parallel laser beams (211);
focusing lenses (22) for focusing the laser beams (211) onto the photosensitive layer (41) of the substrate (4) from the laser sources (21);
a reflective scanner (23) comprising:
two bearings (231) connected to the gentry (12);
a polygonal mirror (232) comprising two terminal sections supported on the bearings (231) and facets (232a) for reflecting the laser beams (211) to the substrate (4) from the focusing lenses (22), wherein each of the facets (232a) does not extend parallel or perpendicular to the optical axis (220) of the corresponding focusing lens (22) while reflecting the corresponding laser beam (211) that go through the corresponding focusing lens (22); and
a motor (M) operatively connected to one of the terminal sections of the polygonal mirror (232); and
a compensating lens (24) located between the polygonal mirror (232) and the substrate (4) and comprising a convex face (241) pointed at the polygonal minor (232) and a planar face (242) pointed at the substrate (4), wherein the laser beams (211), which come from the polygonal mirror (232), enter the compensating lens (24) through the convex face (241) and leave the compensating lens (24) through the planar face (242) before heading for the photosensitive layer (41) of the substrate (4).

2. The reflective mask-less laser direct imaging system in accordance with claim 1, wherein the compensating lens (24) comprises at least one cylindrical lens.

3. The reflective mask-less laser direct imaging system in accordance with claim 1, wherein the compensating lens (24) comprises at least one spherical lens.

4. The reflective mask-less laser direct imaging system in accordance with claim 1, wherein the compensating lens (24) includes at least one aspherical lens.
